(19) United States
(12) Patent Application Publication
(10) Pub. No.: US 2014/0069693 A1
(43) Pub. Date: Mar. 13, 2014

(54) MULTI-LAYER ARTICLE COMPRISING DISCRETE CONDUCTIVE PATHWAYS CONTACTING A CURABLE COMPOSITION COMPRISING BIS-BENZOXAZINE

(71) Applicant: GEORGE ELIAS ZAHR, Glen Mills, PA (US)

(72) Inventor: GEORGE ELIAS ZAHR, Glen Mills, PA (US)

(73) Assignee: E I DU PONT DE NEMOURS AND COMPANY, Wilmington, DE (US)

(21) Appl. No.: 13/606,337

(22) Filed: Sep. 7, 2012

(51) Int. Cl. H05K 1/02; H05K 3/00

(52) U.S. Cl. 174/251; 156/182

(57) ABSTRACT

The present invention deals with a novel multi-layer article useful for preparing flexible printed wiring boards, the multi-layer article comprising discrete conductive pathways contacting a novel curable composition comprising bis-benzoxazine and an amino-functionalized triazine, especially a di-isoimide, and the preparation of encapsulated printed wiring boards, especially flexible printed wiring boards, therefrom. The multi-layer article hereof allows the benefits of bis-benzoxazine as a crosslinkable encapsulant for flexible printed wiring boards to be realized at cure temperatures compatible with existing commercial processes.

### RELATED PATENT APPLICATIONS

This patent application is related to U.S. patent application Ser. No. 13/168,024, entitled “Di-isoimide composition;” U.S. patent application Ser. No. 13/168,062, entitled “Laminate comprising curable epoxy film layer comprising a di-isoimide and process for preparing same;” U.S. patent application Ser. No. 13/168,069, entitled “Printed wiring board encapsulated by adhesive laminate comprising a di-isoimide, and process for preparing same;” and, U.S. patent application Ser. No. 13/168,081, entitled “Process for Preparing a Di-Isoimide Composition;” U.S. patent application Ser. No. ______, CL5787, entitled “Curable composition comprising bis-benzoxazine, method of curing, and the cured composition so formed;” CL5799, entitled “Coated Article Comprising a Curable Composition Comprising Bis-Benzoxazine and an Amino-Functionalized Triazine.”

### FIELD OF THE INVENTION

The present invention deals with a novel multi-layer article comprising discrete conductive pathways contacting a novel curable composition comprising bis-benzoxazine and an amino-functionalized triazine, especially a di-isoimide, and the preparation of encapsulated printed wiring boards, especially flexible printed wiring boards, therefrom.

### BACKGROUND OF THE INVENTION

Thermosettable bis-benzoxazine compositions are used in some applications in the electronics industry. Bis-benzoxazines have been found to exhibit greater dimensional stability under heating, and higher use temperatures than epoxies. They are also less inherently flammable than are epoxies. However, bis-benzoxazines require curing temperatures of ca. 220° C., imparting long shelf-life, but limiting the utility thereof in commercial applications.

Bis-benzoxazines undergo crosslinking to form a rigid material. In some applications, such as flex circuits, bis-benzoxazines are blended with rubber to provide enhanced flexibility, toughness, and adhesive strength. One such application is as a flexible cover layer for flexible printed wiring boards.

### SUMMARY OF THE INVENTION

In one aspect, the present invention provides a curable composition comprising a bis-benzoxazine represented by Structure I

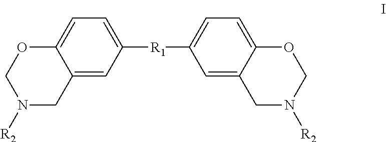

wherein R₁ is a diradical tie molecule, and each R₂ can independently be C₁-C₆ alkyl, acyl, aryl, nitrile, or vinyl;
and,
an amino-functionalized triazine composition represented by Structure II

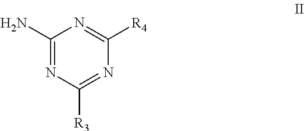

wherein R₃, is H, halogen, hydrocarbyl, hydrocarbyloxy, hydrocarbylthio, amido, sulfonamido, cyclic amino, acyl, morpholino, piperidino, or NR′R″ where R′ and R″ are independently H, alkyl or aromatic, substituted or unsubstituted; and, R₄ is NH₂ or the radical represented by the Structure III

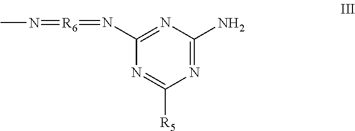

wherein R₅ is H, halogen, hydrocarbyl, hydrocarbyloxy, hydrocarbylthio, amido, sulfonamido, cyclic amino, acyl, morpholino, piperidino, or NR′R″ where R′ and R″ are independently H, alkyl or aromatic, substituted or unsubstituted; and R₆ is an aromatic dianhydride.

In one embodiment, the triazine composition represented by Structure II is a di-isoimide represented by Structure IV and isomeric forms thereof:

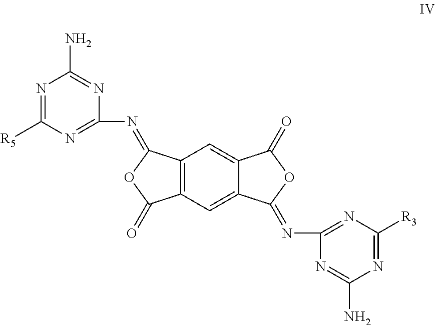

wherein R₃ and R₅ each independently is H, halogen, hydrocarbyl, hydrocarbyloxy, hydrocarbylthio, amido, sulfonamido, cyclic amino, acyl, morpholino, piperidino, or NR′R″ where R′ and R″ are independently H, alkyl or aromatic, substituted or unsubstituted.

In a further aspect, the present invention provides a process comprising heating the curable composition hereof to a temperature in the range of 100 to 250° C. for a period of time in the range of 30 seconds to 5 hours, thereby forming the corresponding cured composition.

In another aspect, the present invention is directed to a coated article comprising a substrate and a curable adhesive bonding layer in adhering contact with said substrate wherein said substrate is a polymeric sheet or film and said curable adhesive bonding layer comprises a curable composition comprising a bis-benzoxazine represented by Structure I, and an amino-functionalized triazine composition represented by Structure II.

In a further aspect, the present invention is directed to a multi-layer article comprising in order a first layer of a first dielectric substrate, a second layer of one or more discrete electrically conductive pathways disposed upon said first dielectric substrate, a third layer of a curable adhesive bonding layer in adhesive contact with said discrete electrically conductive pathways, and a fourth layer of a second, flexible, dielectric substrate adheringly contacting said curable adhesive bonding layer; said curable adhesive bonding layer comprising a curable composition comprising a bis-benzoxazine represented by Structure I and an amino-functionalized triazine composition represented by Structure II.

In another aspect, the present invention provides a process for preparing an encapsulated printed wiring board, the process comprising adhesively contacting the curable adhesive bonding layer of a coated article to at least a portion of discrete conductive pathways disposed upon a dielectric substrate thereby forming a multilayer article; and, applying pressure to the multi-layer article so formed at a temperature in the range of 100 to 250° C. for a period of time in the range of 30 seconds to 5 hours, thereby forming an encapsulated printed wiring board; wherein said multi-layer article comprises in order a first layer of a first dielectric substrate, a second layer of one or more discrete electrically conductive pathways disposed upon said first dielectric substrate, a third layer of a curable adhesive bonding layer adhesively contacting at least a portion of said discrete electrically conducting pathways, and a fourth layer of a second, flexible, dielectric substrate, said curable adhesive bonding layer comprising a curable composition comprising a rubber toughener, a bis-benzoxazine represented by Structure I and an amino-functionalized triazine composition represented by Structure II.

### BRIEF DESCRIPTION OF THE DRAWING

FIG. 1 displays the graphical output of a Differential Scanning calorimeter (DSC) when applied to the curable compositions hereof, showing the features of the curve so generated as described in the examples.

FIG. 2 is a schematic representation of the process hereof for creating the printed wiring board hereof, as described in Example 12.

### DETAILED DESCRIPTION OF THE INVENTION

The bis-benzoxazine suitable for use in the present invention is a thermally crosslinkable compound. Crosslinkable bis-phenylbenzoxazines are available from Huntsman International, LLC. Bis-benzoxazines can undergo self-crosslinking when no separate catalyst or crosslinking agent is present. However, a crosslinking agent is desirable.

According to the present invention, a crosslinkable bis-benzoxazine represented by Structure I is combined with the amino-functionalized triazine represented by Structure II. The combination is then cured to form the crosslinked product. While the operability of the present invention does not depend upon the scientific validity of any particular proposed mechanism, it is believed that the crosslinked product is formed when two amino groups of the amino-functionalized azine react with the heterocyclic rings of two bis-benzoxazines, opening the heterocyclic ring of each benzoxazine moiety to form in each case a phenol and a methylene diamino link between each ring-opened benzoxazine moiety and the amino-functionalized triazine. In that way the triazine compound forms a bridge between two bis-benzoxazines. The term “bis-benzoxazine” will be used herein to refer to the uncured species, and the terms “ring-opened bis-benzoxazine” and “ring-opened benzoxazine moiety” will be used herein to refer to the crosslinked species.

A beneficial result obtained by the use of the curable composition hereof is the achievement of effective crosslinking of bis-benzoxazine at a lower cure temperature than has heretofore been achieved thereby making bis-benzoxazine compositions more compatible with existing processes in printed wiring board technology, among others.

The term “cured” shall refer to the crosslinkable bis-benzoxazine hereof that has undergone substantial crosslinking, the word “substantial” indicating an amount of crosslinking of 75% to 100% of the available heterocyclic rings in the bis-benzoxazine hereof. Preferably more than 90% of the available heterocyclic rings are crosslinked in a “fully cured” composition. The term “uncured” refers to the crosslinkable bis-benzoxazine when it has undergone little crosslinking—that is few if any of the heterocyclic rings of the bis-benzoxazine have undergone ring-opening reaction. The terms “cured” and “uncured” shall be understood to be functional terms. An uncured composition is characterized by solubility in organic solvents and the ability to undergo plastic flow under ambient conditions. A cured composition is characterized by insolubility in organic solvents and the absence of plastic flow under ambient conditions. It is well-known in the art that some of the available cure sites in an uncured crosslinkable composition could be crosslinked and some of the available cure sites in a cured composition could remain uncrosslinked. In neither case, however, are the distinguishing properties of the respective compositions significantly affected.

The art also distinguishes a partially cured composition known as a “B-stage” material. The B-stage material may contain up to about 10% by weight of solvent, and exhibits properties intermediate between the substantially cured and the uncured state. So called “B-staging” can result in the curing of about 20-80% of the available cure sites in a curable material. It is common practice in the art for 40-60% of the cure sites in a B-stage material to have undergone crosslinking.

For the purposes of the present invention the term “curable composition” shall refer to a composition that comprises all the elements necessary for producing a “cured” composition, but that has not yet undergone the “curing process” and is therefore not yet cured. The curable composition is readily deformable and processable, the cured composition is not. The terms “curable” and “cured” are similar in meaning, respectively, to the terms “crosslinkable” and “crosslinked.”

The terms “film” and “sheet” refer to planar shaped articles having a large length and width relative to thickness. Films and sheets differ only in thickness. Sheets are typically defined in the art as characterized by a thickness of 250 micrometers or greater, while films are defined in the art as characterized by a thickness less than 250 micrometers. As used herein, the term “film” encompasses coatings disposed upon a surface by whatever means, and may be cured or uncured.

The term “discrete conductive pathway” as used herein refers to an electrically conductive pathway disposed upon a dielectric substrate in the form of a film or sheet which leads from one point to another on the plane thereof, or through the plane from one side to the other.

There are several terms that are repeated throughout this invention that are described in detail only upon the first mention thereof. However, in order to avoid prolixity the descriptions of the term are not repeated when the term reappears further on in the text. It shall be understood for the purposes of the present invention that when a term is repeated in the text hereof, the description and meaning of that term is unchanged from and the same as that provided for the term upon its first mention. For example, the term “amino-functionalized triazine represented by Structure I” shall be understood each time it appears to encompass all the possible embodiments recited with respect to Structure I upon its first appearance in the text. For another example, the term “solvent” shall be understood to refer to the same set of solvents described for the “solvent” at the first appearance of the term in the text.

For the purposes of this invention, the term “room temperature” is employed to refer to ambient laboratory conditions. As a term of art, “room temperature” is normally taken to mean about 23° C., encompassing temperatures ranging from about 20° C. to about 30° C.

The term “printed wiring board” (PWB) shall refer to a dielectric substrate layer having disposed thereupon a plurality of discrete conductive pathways. The substrate is a sheet or film. In one embodiment of the invention the dielectric substrate is a polyimide film. In a further embodiment, the polyimide film has a thickness of 5-75 micrometers. In one embodiment the discrete conductive pathways are copper.

PWBs suitable for the practice of the present invention can be prepared by well-known and wide-spread practices in the art. Briefly, a suitable PWB can be prepared by a process comprising laminating a copper foil to a dielectric film or sheet using a combination of an adhesive layer, often an epoxy, and the application of heat and pressure. To obtain high resolution circuit lines (≦125 micrometers in width) photoresists are applied to the copper surface. A photoresist is a light-sensitive organic material that when subject to imagewise exposure an engraved pattern in the applied copper layer results when the photoresist is developed and the surface etched. In a suitable PWB, the image is in the form of a plurality of discreet conductive pathways upon the surface of the dielectric film or sheet.

A photoresist can either be applied as a liquid and dried, or laminated in the form, for example, of polymeric film deposited on a polyester release film. When liquid coating is employed, care must be employed to ensure a uniform thickness. When exposed to light, typically ultraviolet radiation, a photoresist undergoes photopolymerization, thereby altering the solubility thereof in a “developer” chemical. Negative photoresists typically consist of a mixture of acrylate monomers, a polymeric binder, and a photoinitiator. Upon imagewise UV exposure through a patterning photomask, the exposed portion of the photoresist polymerizes and becomes insoluble to the developer. Unexposed areas remain soluble and are washed away, leaving the areas of copper representing the conductive pathways protected by the polymerized photoresist during a subsequent etching step that removes the unprotected conductive pathways. After etching, the polymerized photoresist is removed by any convenient technique including dissolution in an appropriate solvent, or surface ablation. Positive photoresists function in the opposite way with UV-exposed areas becoming soluble in the developing solvent. Both positive and negative photoresists are in widespread commercial use. One well-known positive photoresist is the so-called DNQ/novolac photoresist composition.

Any PWB prepared according to the methods of the art is suitable for use in the present invention.

In one embodiment of the curable composition hereof, the amino-functionalized triazine is a di-isoimide represented by Structure IV and isomeric forms thereof

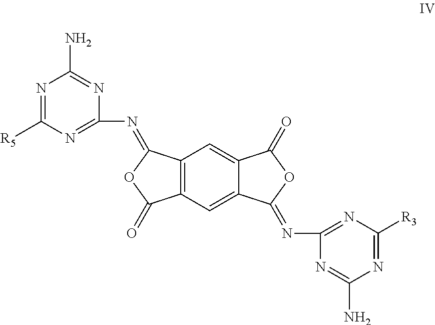

wherein R₃ and R₅ are each individually H, halogen, hydrocarbyl, hydrocarbyloxy, hydrocarbylthio, amido, sulfonamido, cyclic amino, acyl, morpholino, piperidino, or NR′R″ where R′ and R″ are independently H, alkyl or aromatic, substituted or unsubstituted. In one embodiment, R₃ and R₅ are both NH₂.

The principal isomeric form of the di-isoimide of Structure IV is represented by Structure IVa:

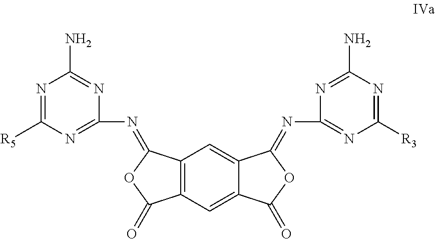

It is believed that the di-isoimide preparation described herein results in a mixture of isomeric forms, with that represented by Structure IV being thermodynamically favored.

The di-isoimide represented by Structures IV and IVa can be prepared by mixing in a reaction solvent, at a temperature in the range of −10 to +160° C., pyromellitic dianhydride (PMDA) with an amino-functionalized triazine represented by the Structure II

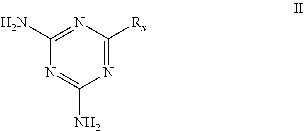

wherein Rₓ is H, halogen, hydrocarbyl, hydrocarbyloxy, hydrocarbylthio, amido, sulfonamido, cyclic amino, acyl, morpholino, piperidino, or NR′R″ where R′ and R″ are independently H, alkyl or aromatic, substituted or unsubstituted. Rₓ corresponds to either R₃ or R₅ in Structures IV and IVa; R₃ and R₅ can be the same or different. In one embodiment, R₃ and R₅ are the same. In one embodiment, R₃ and R₅ are both NH₂.

Suitable reaction solvents include but are not limited to polar/aprotic solvents characterized by a dipole moment in the range of 1.5 to 3.5 D. While the reaction between the amino-functionalized triazine and PMDA takes place in solution, full miscibility of the reactants in the solvent is not necessary. Even limited solubility will permit the reaction to proceed, with additional reactants dissolving as they are consumed in the reaction. Suitable solvents include but are not limited to acetone, methyl ethyl ketone (MEK), methyl isobutyl ketone, ethyl propionate, ethyl-3-ethoxy propionate, cyclohexanone, and mixtures thereof. Mixtures thereof with small amounts (for example, less than 30% by weight) of non-polar solvents such as benzene are also suitable. In one embodiment, the solvent is cyclohexanone.

When the dipole moment of the solvent is below 1.5 D, solubility of melamine, already low, becomes so low that the reaction can take weeks to go to completion. When the dipole moment of the solvent exceeds 3.5 D the rate of the reaction converting the di-isoimide to di-imide can proceed at an inconveniently rapid rate, causing excessive loss of the desired di-isoimide.

To prepare the di-isoimide represented by Structure IV and IVa, wherein R₃ and R₅ are both NH₂, PMDA and melamine are combined in the presence of a reaction solvent, and allowed to react. The reaction temperature can be in the range of −10 to +160° C. The yield of di-imide increases with increasing temperature, at the expense of the di-isoimide. The presence of some di-imide mixed in with the di-isoimide does not necessarily have any particularly negative impact. In some instances, it could be advantageous to use a higher reaction temperature which results in lower selectivity but higher reaction rate.

In general, higher reaction temperature corresponds to faster reaction. Selectivity depends on temperature and the specific choices of dianhydride, triazine, and solvent. For example PMDA and melamine in cyclohexanone produce pure isoimide at 25° C., almost pure isoimide at 50° C., and produce about 80% isoimide at reflux (˜155° C.). PMDA and melamine react faster in N,N-dimethyl formamide (DMF) than in cyclohexanone at the same temperature but the reaction continues on to form imide from a di-isoimide intermediate if the reaction is not stopped in time.

Preferably, the reaction temperature is in the range of room temperature to 100° C. More preferably, the reaction temperature is in the range of room temperature to 50° C.

A water scavenger (such as trifluoroacetic acid) is not required in order to provide the desired di-isoimide, and it is highly preferred to omit a water scavenger in order to avoid having subsequently to remove the water scavenger after reaction is complete.

Maintaining a high degree of mixing during reaction is important for achieving full conversion of the reactants into the di-isoimide product. For example, melamine is of very limited solubility in the suitable reaction solvents. PMDA is also only poorly soluble. In order to achieve high conversion within a commercially viable time frame, it is necessary to maintain good intermixing of the reactants with each other and with the solvent. It is believed that the solution equilibrium for the reactants causes small amounts of reactants to dissolve, and that the thus dissolved reactants react to form a precipitate of the di-isoimide, thereby causing additional reactants to dissolve. This process is believed to continue until the reactants are exhausted, and conversion is quantitative as indicated by the disappearance of the reactant peaks in the infra-red (IR) spectrograph of the solvent dispersion.

Suitable mixing can be achieved using mechanical stirring such as magnetic stirring. A satisfactory state of mixing is one wherein the dispersion of reactants (and product) in the solvent has a uniform appearance with no regions of stagnant solids. It is preferred to stir to maintain a uniform appearance throughout the duration of the reaction.

The present invention provides a curable composition comprising a a bis-benzoxazine represented by Structure I and an amino-functionalized triazine represented by Structure II.

In one embodiment, the bis-benzoxazine is bis-phenylbenzoxazine, wherein each R₂ is phenyl.

In one embodiment, R₁ is C(CH₃)₂. In an alternative embodiment, R₁ is CH₂.

In one embodiment, of the bis-benzoxazine represented by Structure I, each R₂ is phenyl, and R₁ is C(CH₃)₂ or CH₂.

The curable composition hereof contemplates embodiments that contain a solvent, as well as those that do not. In some instances, the curable composition is prepared by dissolving a suitable bis-benzoxazine in a solvent wherein is dispersed a suitable di-isoimide, thereby facilitating the mixing of the reactants to form an embodiment of the curable composition hereof. The curable composition so formed, possibly with some adjustments in viscosity, is then well suited for solution coating onto a substrate, as described infra. Once the coating has been applied, it is often found convenient to drive the solvent off before effecting a cure of the curable composition. After the solvent is driven off, the thus remaining largely solvent-free curable composition can then be advanced to B-stage, or full curing.

In some embodiments, a suitable bis-benzoxazine and a suitable amino-functionalized triazine can be melt processable, and the curable composition hereof prepared by melt mixing. Subsequent formation of a coated substrate could then be effected by melt coating.

In one embodiment, the curable composition further comprises a solvent, as described infra.

In one embodiment, the curable composition is in the B-stage.

It is found in the practice of the invention that the amino-functionalized triazine hereof, particularly the di-isoimide represented by Structures IV and IVa, effect crosslinking of the bis-benzoxazine at ca. 175° C. versus the ca. 220° C. required for curing the bis-benzoxazine in the absence of the amino-functionalized triazine. The di-isoimide hereof is soluble in relatively mild, low boiling point solvents such as cyclohexanone and MEK. This feature of the di-isoimide is of considerable importance in formulations with practical commercial applicability. It is difficult to remove high boiling point solvents from the curable composition once it has been applied without also initiating cure. For adhesive applications, particularly highly critical applications such as the fabrication of encapsulated PWBs as described herein, it is essential to have the solvent removed completely since the adhesive is sealed between the two surfaces it is binding together, and there is no place to which solvent can escape without causing bubbles and voids in the finished product. Bubbles and voids adversely affect the uniformity of the dielectric constant.

In some embodiments, the bis-benzoxazine and the amine-functionalized triazine are advantageously combined in a solvent. Solvents suitable for use in the curable composition hereof include but are not limited to acetone, MEK, cyclohexanone, pentanone, dioxolane, tetrahydrofuran, glycol ethers, propylene glycol methyl ether acetate (PMA), N-methylpyrrolidone, N,N-dimethylacetamide, DMF, dimethyl sulfoxide, N,N-diethylacetamide, N,N-diethylformamide, N,N-dimethylmethoxyacetamide. Preferred solvents are MEK, cyclohexanone, PMA, and DMF. Mixtures of solvents are also suitable.

Referring to Structures IV and IVa, in one embodiment, R₅ and R₇ are both NH₂.

According to the present invention, a suitable amine-functionalized triazine is combined with a bis-benzoxazine to form a curable composition, the bis-benzoxazine represented by Structure I

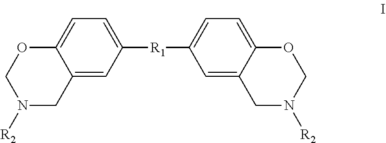

wherein R₁ is a diradical tie molecule and each R₂ can independently be C₁-C₆ alkyl, acyl, aryl; nitrile, or vinyl.

In one embodiment of the bis-benzoxazine suitable for use in the curable composition hereof, each R₂ is phenyl. or substituted phenyl. In a further embodiment, R₂ is phenyl.

In one embodiment R₁ is CH₂, C(CH₃)₂, S, dicyclopentadienyl, or phenolphthalein. In a further embodiment, R₁ is C(CH₃)₂.

While not required, the curable composition hereof can further comprise one or more epoxies. Suitable epoxies include but are not limited to polyfunctional epoxy glycidyl ethers of polyphenol compounds, polyfunctional epoxy glycidyl ethers of novolak resins, alicyclic epoxy resins, aliphatic epoxy resins, heterocyclic epoxy resins, glycidyl ester epoxy resins, glycidylamine epoxy resins, and glycidylated halogenated phenol epoxy resins. Preferred epoxies include epoxy novolacs, biphenol epoxy, bisphenol-A epoxy and naphthalene epoxy. Preferred epoxies are oligomers having 1-5 repeat units. Most preferably the epoxy is bisphenol-A or novolac epoxy, especially bisphenol A diglycidyl ether.

Suitable epoxies can be derivatized in any manner described in the art. In particular they can be halogenated, especially by bromine to achieve flame retardancy, or by fluorine.

The amine-functionalized triazine, preferably the di-isoimide represented by Structures IV and IVa, can serve both as a curing catalyst and/or as a curing agent in the curable composition hereof. In a further embodiment, the curable composition hereof can further comprise an additional curing agent. Any curing agent known in the art can be used in the compositions and processes disclosed herein. Suitable curing agents include organic acid anhydrides and phenols.

In an alternative embodiment, the curable composition hereof does not include a separate curing agent. It is found in the practice of this embodiment of the invention that the nucleophilic character of the amine group is much reduced by the presence of the triazine ring and the isoimide linkage. It is further found that once one of the amine groups on the ring undergoes reaction, the second amine group becomes still less reactive. Therefore in formulating the curable composition in this embodiment, it is found that satisfactory results are achieved by treating each mole of the di-isoimide of Structures IV and IVa as representing four equivalents from the standpoint of crosslinking the bis-benzoxazine,. It has been found in the practice of the invention that a practical formulation of the curable composition hereof contains approximately a 50% excess in equivalents of bis-benzoxazine plus equivalents of epoxy (when it is present) has been found to be satisfactory.

The curable composition hereof can include any and all of the numerous additives commonly incorporated into epoxy formulations in the art. This can include flame retardants, rubber or other tougheners, inorganic particles, plasticizers, surfactants and rheology modifiers.

For those end-use applications wherein flexibility and toughness are required, a rubber toughener is highly desirable in the curable composition hereof. Particularly suitable are rubbers functionalized with polar groups that provide some mixing compatibility with the other components of the curable composition.

When an epoxy is present, an additional curing agent may be desirable preferably a phenol or an anhydride. The curing agent is added in quantities based on equivalent weight. In the case of phenolic curing agents, 0.3-0.9 equivalent of phenol for each equivalent of epoxy has been found to be suitable. With anhydride curing agents, 0.4-0.6 equivalent of anhydride has been found to be suitable for each equivalent of epoxy.

Suitable phenol curing agents include biphenol, bisphenol A, bisphenol F, tetrabromobisphenol A, dihydroxydiphenyl sulfone, novolacs and other phenolic oligomers obtained by the reaction of above mentioned phenols with formaldehyde. Suitable anhydride curing agents are nadic methyl anhydride, methyl tetrahydrophthalic anhydride and aromatic anhydrides.

Aromatic anhydride curing agents include but are not limited to aromatic tetracarboxylic acid dianhydrides such as pyromellitic dianhydride, biphenyltetracarboxylic acid dianhydride, benzophenonetetracarboxylic acid dianhydride, oxydiphthalic acid dianhydride, 4,4′-(hexafluoroisopropylidene)diphthalic acid dianhydride, naphthalene tetracarboxylic acid dianhydride, thiophene tetracarboxylic acid dianhydride, 3,4,9,10-perylene tetracarboxylic acid dianhydride, pyrazine tetracarboxylic acid dianhydride, and 3,4,7,8-anthraquinone tetracarboxylic acid dianhydride. Other suitable anhydride curing agents are oligomers or polymers obtained by the copolymerization of maleic anhydride with ethylene, isobutylene, vinyl methyl ether and styrene. Maleic anhydride grafted polybutadiene can also be used as a curing agent.

Suitable tougheners are low molecular weight elastomers or thermoplastic elastomers and contain functional groups for reaction with bis-benzoxazine and/or with epoxy resin when it is present. Examples are polybutadienes, polyacrylics, phenoxy resin, polyphenylene ethers, polyphenylene sulfide and polyphenylene sulfone, and carboxyl-functionalized elastomers.

Suitable tougheners include but are not limited to carboxyl-terminated butadiene nitrile elastomers (CTBN), epoxy adducts of CTBN, amine terminated butadiene nitrile elastomers (ATBN), polyol elastomers and amine terminated polyol elastomers.

Carboxyl-functionalized elastomers are preferred.

In one embodiment, the di-isoimide can be pre-dispersed in the solvent in which it was prepared. In an alternative embodiment, the di-isoimide may be added as particles to a solution of bis-benzoxazine and epoxy (if present) and dispersed therein using mechanical agitation.

In one embodiment, the curable composition hereof comprises an epoxy of the bisphenol A type; a phenolic or anhydride curing agent; a rubber toughener comprising a carboxyl functionalized elastomer; R₂ is phenyl or substituted phenyl; R₁ is CH₂, C(CH₃)₂, S, dicyclopentadienyl, or phenolphthalein; the amino-functionalized triazine is a di-isoimide represented by Structure IV and isomeric forms thereof

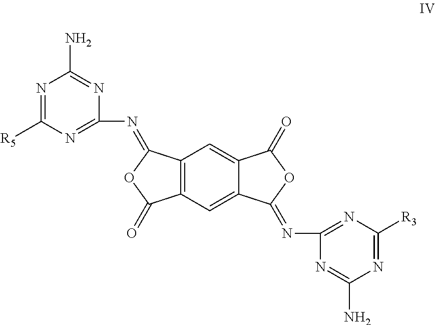

and, wherein R₃ and R₅ are each NH₂. In a further aspect, the present invention provides a process for preparing a cured composition from the curable composition hereof by heating the curable composition to a temperature in the range of 100 to 250° C. for a period of time in the range of 30 seconds to 5 hours. For critical adhesive applications any solvent that is present needs to be removed completely before curing, as described in the Examples, infra.

The viscosity of the uncured composition can be adjusted by either adding solvent to decrease the viscosity, or by evaporating solvent to increase viscosity. In the case of a molten composition, viscosity can often be adjusted by changes in temperature of the melt.

The curable composition can be poured into a mold, followed by curing, to form a shaped article of any desired shape. One such process known in the art is reaction injection molding. In particular, the composition can be used in forming films or sheets, or coatings. The viscosity of the curable composition is adjusted as appropriate to the requirements of the particular process. Films, sheets, or coatings are suitably prepared by any process known in the art. Suitable processes include but are not limited to solution casting, spray-coating, spin-coating, or painting. A preferred process is solution casting using a Meyer rod for draw down of the casting solution deposited onto a substrate. The substrate can be treated to improve the wetting and release characteristics of the coating. Solution cast films are generally 10 to 75 micrometers in thickness. The solution casting of a solution/dispersion such as that formed in some embodiments of the curable composition hereof onto a substrate film or sheet to form a laminated article is further described in the specific embodiments, infra.

Melt casting or melt molding of those embodiments of the curable composition hereof that are formed by melt blending, using means well-known in the art is also suitable.

In another aspect, the present invention is directed to a coated article comprising a substrate and a coating adheringly deposited thereupon wherein said substrate is a polymeric sheet or film and said coating comprises the curable composition hereof, the curable composition comprising a bis-benzoxazine represented by Structure I, an amine-functionalized triazine composition represented by Structure II, and a rubber. In one embodiment, the curable composition further comprises a solvent. In one embodiment, the substrate is a polyimide film. In a further embodiment the polyimide film has a thickness of 10-50 micrometers.

In one embodiment of the coated article hereof, the curable composition thereof further comprises a solvent including but not limited to acetone, MEK, cyclohexanone, pentanone, dioxolane, tetrahydrofuran, glycol ethers, propylene glycol methyl ether acetate (PMA), N-methylpyrrolidone, N,N-dimethylacetamide, DMF, dimethyl sulfoxide, N,N-diethylacetamide, N,N-diethylformamide, N,N-dimethylmethoxyacetamide. Preferred solvents are MEK, cyclohexanone, PMA, DMF, and mixtures thereof.

In one embodiment of the coated article hereof, in the curable composition thereof, in the bis-benzoxazine represented by Structure I, each R₂ is phenyl, R₁ is C(CH₃)₂ or CH₂.

In one embodiment of the coated article hereof, in the curable composition thereof the amine-functionalized triazine is the di-isoimide represented by Structures IV and IVa wherein R₃ and R₅ are both NH₂.

In one embodiment, the coating has a thickness of 10 to 75 micrometers.

In one embodiment, the substrate is coated on both sides thereof. In a further embodiment, the coatings on both sides are chemically identical.

In a further aspect, the present invention is directed to a multi-layer article comprising in order a first layer of a first dielectric substrate, a second layer of one or more discrete electrically conductive pathways disposed upon said first dielectric substrate, a third layer of a curable adhesive bonding layer in adhesive contact with said discrete electrically conductive pathways, and a fourth layer of a second, flexible, dielectric substrate adhereingly contacting said curable adhesive bonding layer, said curable adhesive bonding layer comprising a curable composition comprising a rubber toughener, a bis-benzoxazine represented by Structure I and an amino-functionalized triazine composition represented by Structure II.

In one embodiment of the multi-layer article hereof, in the curable composition thereof, in the bis-benzoxazine represented by Structure I, each R₂ is phenyl, and R₁ is C(CH₃)₂ or CH₂.

In one embodiment of the multi-layer article hereof, in the curable composition thereof the amine-functionalized triazine is the di-isoimide represented by Structures IV and IVa wherein R₃ and R₅ are both NH₂.

In one embodiment of the multi-layer article hereof, the first substrate is a polyimide film having a thickness of 10-50 micrometers.

In one embodiment of the multi-layer article hereof, the electrically conductive pathways are copper.

In a further embodiment of the multi-layer article hereof, the copper electrically conductive pathways are characterized by a thickness of 10-50 micrometers and lines and spacing from 10-150 micrometers.

In one embodiment of the multi-layer article hereof, the second dielectric substrate is a polyimide film or sheet. In a further embodiment said second dielectric substrate is a fully aromatic polyimide film or sheet. In a still further embodiment, said second dielectric substrate is a film or sheet comprising a polyimide that is the condensation product of PMDA and 4,4′-ODA. In a still further embodiment, said second dielectric substrate is a fully aromatic polyimide film having a thickness of 10-50 micrometers.

In one embodiment of the multi-layer article hereof, the first dielectric substrate is a polyimide film or sheet. In a further embodiment said first dielectric substrate is a fully aromatic polyimide film or sheet. In a still further embodiment, said first dielectric substrate is a film or sheet comprising a polyimide that is the condensation product of PMDA and 4,4′-ODA. In a still further embodiment, said first dielectric substrate is a fully aromatic polyimide film having a thickness of 10-50 micrometers.

In another embodiment of the multi-layer article hereof, both said dielectric substrates are polyimide film or sheet, as described supra.

The multi-layer article hereof is conveniently formed by contacting a coating side of the coated article hereof to the conductive pathways disposed upon the first dielectric substrate. The multi-layer article hereof has several embodiments that differ from one another in the degree of consolidation. In one embodiment, the multi-layer article hereof is formed simply by disposing upon a horizontal surface a first dielectric substrate having one or more discrete conductive pathways disposed upon at least one surface thereof, where said conductive pathways are facing upward; followed by placing a coated side of the laminated article hereof in contact with the conductive pathways, thereby preparing a so-called “green” or uncured multi-layer article hereof.

In a further embodiment, the green multi-layer article hereof is subject to pressure thereby causing some consolidation. In a further embodiment the green multi-layer article is subject to both pressure and heat. The temperature may only be sufficient to induce a small amount of crosslinking or curing. This represents a so-called “B-stage” curing—an intermediate level of consolidation that causes the multi-layer article to have some structural integrity while retaining formability and processability. The B-stage can be followed by complete curing. Alternatively, complete curing can be effected in a single heating and pressurization step from the green state. In still another embodiment, the coating of the coated article can be in the B-stage before application to the discrete conductive pathways in the formation of the multi-layer article hereof.

In one embodiment of the multi-layer article hereof, the first dielectric substrate bears conductive pathways on both sides, permitting the formation of the multi-layer construction described supra on both sides of the first dielectric substrate.

In another embodiment of the multi-layer article hereof, the second dielectric substrate is coated on both sides with the curable composition hereof, as described supra for the single sided coated substrate.

In still a further embodiment, the first dielectric substrate bears conductive pathways on both sides, and the second dielectric substrate bears a coating of the curable composition hereof on both sides. This embodiment permits printed wiring boards hereof to be constructed with an indefinite number of repetitions of the basic structure of the multi-layer article.

In a further embodiment, at least a portion of the conductive pathways disposed upon one side of the first dielectric substrate are in electrically conductive contact with at least a portion of the conductive pathways disposed upon the other side of the first dielectric substrate through so-called “vias” that serve to connect the two sides of the dielectric substrate.

In another aspect, the present invention provides a third process, a process for preparing an encapsulated printed wiring board, the process comprising adhesively contacting the curable composition hereof disposed upon the surface of the coated article hereof to at least a portion of the discrete conductive pathways disposed upon a dielectric substrate thereby forming a multilayer article; and, applying pressure to the multi-layer article so formed at a temperature in the range of 100 to 250° C. for a period of time in the range of 30 seconds to 5 hours, thereby forming an encapsulated printed wiring board.

In one embodiment, the third process hereof further comprises extracting solvent present in the curable composition hereof before applying pressure to the multi-layer article hereof. Solvent extraction can be effected conveniently by heating the multi-layer article hereof in an air circulating oven set at 110° C. for a period of time ranging from 2-20 minutes.

In one embodiment of the process for forming an encapsulated printed wiring board, in the multi-layer article, in the curable composition, in the bis-benzoxazine represented by Structure I, each R₂ is phenyl, R₁ is C(CH₃)₂ or CH₂, S, dicyclopentadienyl, or phenolphthalein and each of R₁ and each of R₃ is H.

In one embodiment of the process for forming an encapsulated printed wiring board, in the multi-layer article, in the curable composition thereof the amine-functionalized triazine is the di-isoimide represented by Structures IV and IVa wherein R₅ and R₇ are both NH₂.

In one embodiment of the process for forming an encapsulated printed wiring board, in the multi-layer article, the first layer is a polyimide film having a thickness of 10-50 micrometers.

In one embodiment of the process for forming an encapsulated printed wiring board, in the multi-layer article, the electrically conductive pathways are copper.

In one embodiment of the process for forming an encapsulated printed wiring board, in the multi-layer article, the copper electrically conductive pathways are characterized by a thickness of 10-50 micrometers and lines and spacing from 10-150 micrometers.

In one embodiment of the process for forming an encapsulated printed wiring board, in the multi-layer article, the curable composition further comprises a solvent. In a further embodiment, said solvent is MEK, cyclohexanone, PMA, DMF, or a mixture thereof.

In one embodiment of the process for forming an encapsulated printed wiring board, in the multi-layer article, the second dielectric substrate is a polyimide film or sheet. In a further embodiment said second dielectric substrate is a fully aromatic polyimide film or sheet. In a still further embodiment, said second dielectric substrate is a film or sheet comprising a polyimide that is the condensation product of PMDA and 4,4′-ODA. In a still further embodiment, said second dielectric substrate is a fully aromatic polyimide film having a thickness of 10-50 micrometers.

The invention is further described in the following specific embodiments though not limited thereby.

### EXAMPLES

### Material and Methods

A. Preparation of di-isoimide

### Determining Reaction Completion Point

In the following examples, infrared spectroscopy (IR) was employed to determine the end-point of the di-isoimide preparation. Small aliquots of the reacting medium were withdrawn by dropper-full, dried in a vacuum oven with N₂ purge at about 60° C. for about 60 minutes. Following conventional methodology for preparing solids for IR spectroscopic analysis, the resulting powder was then compounded with KBr followed by the application of pressure to the resulting compound, thereby forming a test pellet. IR absorption peaks at 1836 cm⁻¹ and 1769 cm⁻¹ were monitored to follow the increase in the concentration of the di-isoimide product. Similarly, IR absorption peaks at 1856 cm⁻¹ and 1805 cm⁻¹ characteristic of PMDA and 1788 cm⁻¹ characteristic of melamine were monitored to follow the consumption of reactants. When the PMDA and melamine peaks became undetectable, the reaction was considered to be complete.

Peaks at 1788 cm⁻¹ and 1732 cm⁻¹ characteristic of imide were also monitored to follow the synthesis of any imide by-product of the present process.

The time to reaction completion was observed to vary considerably with the reaction temperature and the particular choice of solvent.

### Reaction Medium

Both melamine and PMDA are only slightly soluble in the solvents employed herein so it was necessary to maintain good mixing during reaction to ensure a high degree of conversion. Without constant vigorous mixing, the solids settled and the reaction slowed down or stopped. The amount of energy that was needed for mixing was determined by observation. When the dispersion was of uniform appearance and no stagnant solid phase was observed, mixing was deemed to be of sufficient energy. The di-isoimide product formed into platelet particles with dimensions in the hundreds of nanometers range. These platelet particles also remained suspended with mixing. By the time reaction was completed, no detectable amounts of PMDA or melamine were present in the reaction mixture—all the suspended particles were di-isoimide, or, in some instances, di-isoimide with some imide mixed in.

### B. Printed Wiring Board

A Pyralux® AC182000R copper clad laminate sheet (Dupont Company) was etched according to a common commercial etching process to form a series of parallel copper conductive strips 35 micrometers high, 100 micrometers wide, and spaced 100 micrometers apart. This was used in Examples 9-12, and is referred to therein as “a PWB test sheet.” Information on methods for preparing printed wiring boards can found in Chris A. Mack, Fundamental Principles of Optical Lithography The Science of Microfabrication, John Wiley & Sons, (London: 2007). Hardback ISBN: 0470018933; Paperback ISBN: 0470727306.

### C. Reagents And Labware

Except where otherwise noted, all reagents were obtained from Sigma Aldrich Chemical Company.

The curable compositions of the invention as prepared in the Examples were combined in a 100 ml screw top glass vial provided with a magnetic stirring bar. Reactions were conducted with the screw top loosely attached. A vial of this sort is referred to simply as “a vial” in the text infra.

### D. Differential Scanning Calorimetry

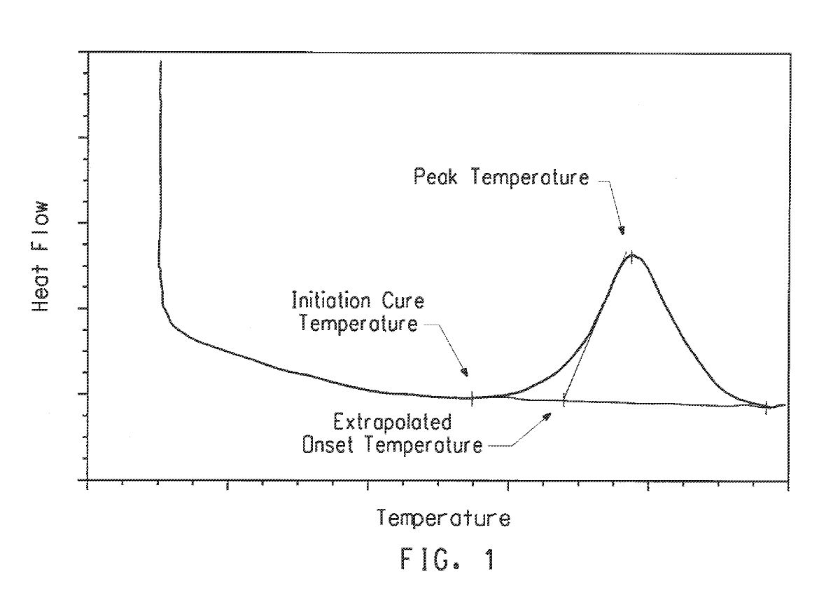

Samples of the curable compositions were analyzed by Differential Scanning calorimetry (DSC) (Model Q-2000, TA instruments) at a heating rate of 5° C./min. The DSC was run to identify the exotherm believed to correspond to the curing reaction. FIG. 1 depicts a typical DSC curve, with the critical features identified. The Initiation Cure Temperature is the temperature at which the exotherm is first observed to depart from the baseline. The Extrapolated Onset Temperature is determined using built in software in the DSC instrument in which the linear portion of the rising curve is extrapolated back to the zero-point of energy. Finally the Peak Temperature is the temperature at which the curing exotherm reaches its peak. Each of these values was measured for each sample produced in the Examples, and are tabulated in Table 1.

### Comparative Example A

8.0 g of a copolymer of butadiene and acrylonitrile modified to contain free carboxylic groups (Nipol 1072J from Zeon Chemicals) was dissolved in 45.3 g of MEK (methyl ethyl ketone). 2.0 g of Bisphenol-A based Benzoxazine (Araldite® MT 35600 from Huntsman Advanced Materials) was dissolved in 2.0 g of MEK. The two solutions so prepared were mixed in a vial. 7.0 g of Phosmel® 200 Fine flame retardant (Nissan Chemical Industries) was then added to the flask, and mixed in, to form a first solution/dispersion. 3.0 g of an epoxy-rubber adduct (HyPox®RK84L from CVC Thermoset Specialties) was dissolved in 3.0 g of MEK to form a second solution. The second solution was added to the first solution/dispersion thereby forming a second solution/dispersion. The second solution/dispersion so formed was homogenized for 2.5 minutes (Silverson model L5M homogenizer) to a dispersion having a visually uniform appearance, thereby forming a coating composition. The thus prepared coating composition was then mechanically stirred continuously until coating, described infra, was commenced.

The second solution/dispersion so prepared was coated onto 12 micrometer thick Kapton® 50FPC polyimide film using a 0.007 in. gauge (177.8 micrometer) doctor blade followed by removal of the solvent by placing the thus-cast film and substrate in a vacuum oven at 60° C. for one hour. An approximately 25 micrometer thick coating was obtained following solvent removal.

A DSC (differential Scanning calorimetry) measurement was done on a sample of the coating. Data are shown in Table 1 and definition of terms is shown in FIG. 1.

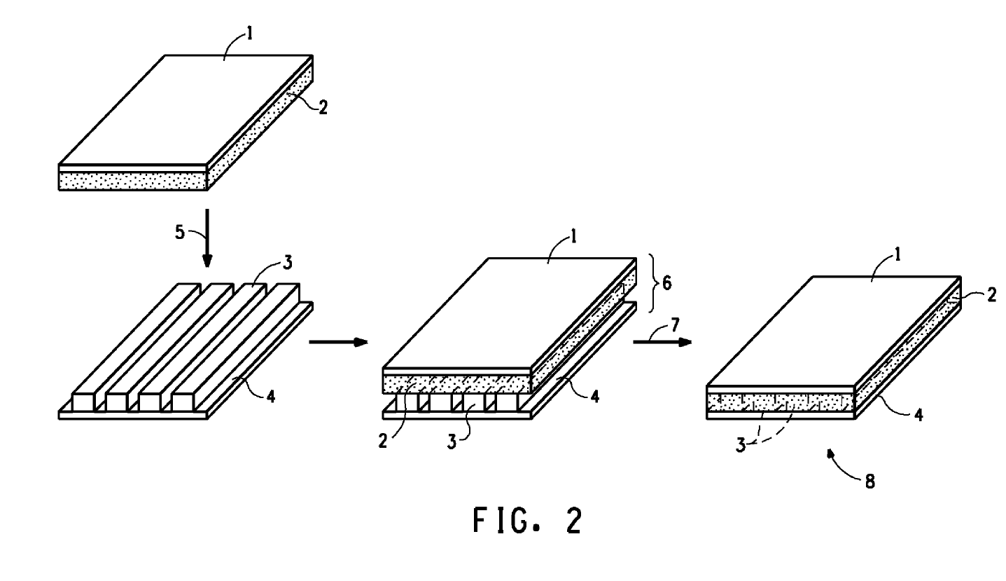

The thus prepared coated Kapton® 50FPC polyimide film was then used as a cover-layer on the PWB test sheet. Referring to FIG. 2, the coated Kapton® 50FPC polyimide film, 1, coated with the curable composition, 2, thus prepared was contacted, 5, to the copper conductive strips, 3, of the PWB test sheet, 4, the curable composition, 2, being in direct contact with the copper conductive strips, 3. The printed wiring board thereby formed, 6, was then consolidated, 7, under vacuum in an OEM Laboratory Vacuum Press by holding the printed wiring board at 177° C. and 2.25 MPa for 80 minutes, thereby forming an encapsulated flexible printed wiring board, 8, having fully encapsulated copper conductive pathways.

0.5 in.-wide sample strips were cut from the thus prepared encapsulated flexible printed wiring board. Adhesion of the cured encapsulant to the Cu-circuit elements was measured using a hand held lab load cell (Mark-10 model MG2). The encapsulated FWB was prepared with the ends of the two substrate films not glued together so that they could be separately clamped. One film was held between thumb and forefinger, and the other clamped in the load cell. The two strips were then pulled apart and the load cell reading recorded. The average peel strength for five specimens was 3.92 lb/in with average deviation of 0.32 lb/in

### Example 1

29.04 g of melamine, 25.11 g of PMDA and 150 g of cyclohexanone were mixed using a mechanical stirrer in a vial. The mixture was stirred for eight days until conversion was complete. The reaction completion was confirmed by IR spectroscopy. A sample from the reaction mixture was dried in a vacuum oven. IR spectra of the final solid product showed the disappearance of the PMDA peaks at 1856 & 1805 cm⁻¹ and melamine peak at 1558 cm⁻¹ and the appearance of the isoimide peaks at 1836 & 1769 cm⁻¹.

The materials and procedures employed in Comparative Example A were replicated except that 1. 0 gram of the thus prepared di-isoimide pre-dispersed in 4.0 g of cyclohexanone were combined with the other ingredients to form the coating composition, and 6 g of Phosmel® 200 Fine were employed instead of 7 g.

An approximately 25 micrometer thick coating was prepared in the same manner as in Comparative Example A. A DSC measurement was done on a sample of the coating. Data are shown in Table 1.

An encapsulated printed wiring board was prepared employing the thus prepared coated Kapton® FPC polyimide film following the method of Comparative Example A. In the resulting cured construction, the copper conductive pathways were fully encapsulated.

The average peel strength for five specimens, determined as in Comparative Example A, was 5.84 lb/in with average deviation of 0.36 lb/in

### Example 2

The materials and procedures employed in Example 1 were replicated except that 0.4 g of the di-isoimide of Example 1 was pre-dispersed in 1.6 g of cyclohexanone, and 6.6 g of Phosmel® 200 Fine were employed instead of 6 g.

An approximately 25 micrometer thick coating was prepared in the same manner as in Comparative Example A. A DSC measurement was done on a sample of the coating. Data are shown in Table 1.

An encapsulated printed wiring board was prepared employing the thus prepared coated Kapton® FPC polyimide film following the method of Comparative Example A. In the resulting cured construction, the copper conductive pathways were fully encapsulated.

The average peel strength for five specimens, determined as in Comparative Example A, was 6.87 lb/in with average deviation of 0.12 lb/in

### Example 3

0.20 gram of the melamine, 7.51 g of a copolymer of ethylene and methyl acrylate modified to contain free carboxylic groups (Vamac GLS from DuPont) was dissolved in 30.05 g of MEK. 0.38 g of bisphenol-A based bis-benzoxazine (Araldite® MT 35600 from Huntsman Advanced Materials) was dissolved in 1.12 g of MEK. The solutions so formed were mixed in a vial. 12.0 g of Phosmel® ® 200 Fine was then added and mixed in, to form a first solution/dispersion. 7.51 g of an epoxy-rubber adduct (HyPox® RK84L from CVC Thermoset Specialties) and 2.4 g of JER® 1004 (solid epoxy resin from Japan Epoxy Resins Co., Ltd.) were dissolved in 14.51 g of MEK to form a second solution. The second solution was added to the first solution/dispersion thereby forming a second solution/dispersion. The second solution/dispersion so formed was homogenized for 2.5 minutes (Silverson model L5M homogenizer) to a dispersion having a visually uniform appearance, thereby preparing a coating composition. The coating composition so prepared was then mechanically stirred continuously until coating was commenced.

The coating composition so prepared was coated onto 12 micrometer thick Kapton® 50FPC polyimide film using a 0.007 in. gauge (177.8 micrometer) doctor blade followed by removal of the solvent by placing the thus-cast film and substrate in a vacuum oven at 60° C. for one hour, to form an approximately 25 micrometer thick coating.

A DSC measurement was done on a sample of the coating. Data are shown in Table 1.

### Example 4

0.52 g of the di-isoimide prepared in Example 1 was dispersed in 2.11 g of cyclohexanone. 7.38 g of Vamac GLS was dissolved in 29.51 g of MEK. 0.37 g of Araldite® MT 35600 was dissolved in 1.11 g of MEK. The solutions and dispersion thus prepared were combined in a vial. 12.0 g of Phosmel® 200 Fine was then mixed in, to form a first solution/dispersion. 7.38 g of HyPox® RK84L and 2.36 g of JER® 1004 solid epoxy resin were dissolved in 13.37 g of MEK to form a second solution. The second solution was added to the first solution/dispersion thereby forming a second solution/dispersion. The second solution/dispersion so formed was homogenized for 2.5 minutes (Silverson model L5M homogenizer) to a dispersion having a visually uniform appearance, thereby preparing a coating composition. The thus prepared coating composition was then mechanically stirred continuously until coating was commenced. The coating composition so prepared was coated onto 12 micrometer thick Kapton® 50FPC polyimide film using a 0.007 in. gauge (177.8 micrometer) doctor blade followed by removal of the solvent by placing the thus-cast film and substrate in a vacuum oven at 60° C. for one hour, to form an approximately 25 micrometer thick coating.

A DSC measurement was done on a sample of the coating. Data are shown in Table 1.

### Example 5

0.50 g of a 60% solids solution of phenol novolac resin containing an amino-functionalized triazine ring and amino functions in MEK (PHENOLITE® LA-7054 from Dainippon Ink & Chemicals) was combined in a flask with a solution of 7.39 g of a Vamac GLS dissolved in 29.56 g of MEK, and a solution of 0.56 g of Araldite® MT 35600 dissolved in 1.68 g of MEK. 12.0 Phosmel® 200 Fine was then added and mixed in, to form a first solution/dispersion. 7.39 g of HyPox®RK84L and 2.36 g of JER® 1004 were dissolved in 7.40 g of MEK to form a second solution. The second solution was added to the first solution/dispersion thereby forming a second solution/dispersion. The second solution/dispersion so formed was homogenized for 2.5 minutes (Silverson model L5M homogenizer) to a dispersion having a visually uniform appearance, thereby forming a coating composition. The thus homogenized mixture was then mechanically stirred continuously until coating, described infra, was commenced. The epoxy solution/dispersion so prepared was coated onto 12 micrometer thick Kapton® 50FPC polyimide film using a 0.007 in. gauge (177.8 micrometer) doctor blade followed by removal of the solvent by placing the thus-cast film and substrate in a vacuum oven at 60° C. for one hour, to form an approximately 25 micrometer thick coating.

A DSC measurement was done on a sample of the coating. Data are shown in Table 1.

TABLE 1

| | Initiation Cure | Extrapolated onset | Peak |
|---|---|---|---|
| Sample | temperature (° C.) | temperature (° C.) | temperature (° C.) |
| Comparative | 165° C. | 194.0° C. | 218.7° C. |
| example 1 | | | |
| example 1 | 130° C. | 152.3° C. | 197.4° C. |
| example 2 | 143° C. | 166.6° C. | 201.1° C. |
| example 3 | 137° C. | 144.0° C. | 217.3° C. |
| example 4 | 135° C. | 146.1° C. | 197.9° C. |
| example 5 | 159° C. | 174.6° C. | 219.1° C. |

### Example 6

1.50 g of the di-isoimide prepared in Example 1 was dispersed in 6.14 g of cyclohexanone. 10.50 g Nipol 1072J was dissolved in 59.5 g of MEK. 2.63 g Araldite® MT 35600 was dissolved in 2.63 g of MEK. The solutions and dispersion so prepared were mixed in a vial. 10.50 g of Phosmel® 200 Fine was then added to the vial and mixed in, to form a first solution/dispersion. 4.28 g of HyPox®RK84L and 0.60 g of bisphenol-A diglycidyl ether epoxy resin (Epon 828 from Momentive Specialty Chemicals Inc.) were dissolved in 4.28 g of MEK to form a second solution. The second solution was added to the first solution/dispersion thereby forming a second solution/dispersion. The second solution/dispersion was homogenized for 2.5 minutes (Silverson model L5M homogenizer) to a dispersion having a visually uniform appearance, thereby forming a coating composition. The thus homogenized mixture was then mechanically stirred continuously until coating was commenced.

The coating composition so prepared was coated onto 12 micrometer thick Kapton® 50FPC polyimide film using a 0.007 in. gauge (177.8 micrometer) doctor blade followed by removal of the solvent by placing the thus-cast film and substrate in an air circulating oven at 110° C. for five minutes, to form an approximately 25 micrometer thick coating.

An encapsulated printed wiring board was prepared employing the thus prepared coated Kapton® FPC polyimide film following the method of Comparative Example A. In the resulting cured construction, the copper conductive pathways were fully encapsulated. The adhesion of the coated film to the PWB test sheet was determined to be 1.05 N/mm (Newton/millimeter) according to ISO 6133 IPC-TM-650 2.4.9 using a German wheel attached to an Instron machine.

### Example 7

1.50 g of the di-isoimide prepared in Example 1 was dispersed in 6.14 g of cyclohexanone. 7.50 g of Nipol® 1072J was dissolved in 42.5 g of MEK. 1.50 g of Araldite® MT 35600 was dissolved in 1.50 g of MEK. The solutions and dispersion thus prepared were combined in a vial. 10.50 g of Phosmel® 200 Fine was then added to the flask and mixed in to form a first solution/dispersion. 8.40 g of HyPox®RK84L and 0.60 g of Epon 828 were dissolved in 8.40 g of MEK to form a second solution. The second solution was added to the first solution/dispersion thereby forming a second solution/dispersion. The second solution/dispersion so formed was homogenized for 2.5 minutes (Silverson model L5M homogenizer) to a dispersion having a visually uniform appearance, thereby forming a coating composition. The thus homogenized mixture was then mechanically stirred continuously until coating was commenced.

The coating composition so prepared was coated onto 12 micrometer thick Kapton® 50FPC polyimide film using a 0.007 in. gauge (177.8 micrometer) doctor blade followed by removal of the solvent by placing the thus-cast film and substrate in an air circulating oven at 110° C. for five minutes, to form an approximately 25 micrometer thick coating.

An encapsulated printed wiring board was prepared employing the thus prepared coated Kapton® FPC polyimide film following the method of Comparative Example A. In the resulting cured construction, the copper conductive pathways were fully encapsulated. The adhesion of the coated film to the PWB test sheet was determined to be 0.98 N/mm (Newton/millimeter) according to ISO 6133 IPC-TM-650 2.4.9 using a German wheel attached to an Instron machine.

### Example 8

0.35 g of the di-isoimide prepared in Example 1 was dispersed in 1.42 g of cyclohexanone. 7.30 g of Vamac GLS was dissolved in 29.54 g of MEK. 0.73 g Araldite® MT 35600 was dissolved in 0.73 g of MEK. The solutions and dispersion so prepared were mixed in a vial. 12.00 g of Phosmel® 200 Fine was then added to the vial and mixed in, to form a first solution/dispersion. 7.29 g of HyPox® RK84L was dissolved in 7.29 g of MEK. To the HyPox/MEK solution was added 6.67 g of a 35% solution of ultra high molecular weight epoxy resin of bisphenol-A diglycidyl ether, dissolved in a 75/25 wt/wt mixture of MEK and propylene glycol methyl ether (PGME) (Eponol Resin 53-BH-35 solution from Momentive Specialty Chemicals Inc., “formerly known as Hexion Specialty Chemicals Inc.”), thereby forming a second solution. The second solution was added to the first solution/dispersion thereby forming a second solution/dispersion. The second solution/dispersion so formed was homogenized for 2.5 minutes (Silverson model L5M homogenizer) to a dispersion having a visually uniform appearance, thereby forming a coating composition. The thus homogenized mixture was then mechanically stirred continuously until coating, was commenced. The coating composition so prepared was coated onto 12 micrometer thick Kapton® 50FPC polyimide film using a 0.007 in. gauge (177.8 micrometer) doctor blade followed by removal of the solvent by placing the thus-cast film and substrate in an air circulating oven at 110° C. for five minutes, to form an approximately 25 micrometer thick coating.

An encapsulated printed wiring board was prepared employing the thus prepared coated Kapton® FPC polyimide film following the method of Comparative Example A. In the resulting cured construction, the copper conductive pathways were fully encapsulated. The adhesion of the coated film to the PWB test sheet was determined to be 0.64 N/mm (Newton/millimeter) according to ISO 6133 IPC-TM-650 2.4.9 using a German wheel attached to an Instron machine.

I claim:

1. A multi-layer article comprising in order a first layer of a first dielectric substrate, a second layer of one or more discrete electrically conductive pathways disposed upon said first dielectric substrate, a third layer of a curable adhesive bonding layer in adhesive contact with said discrete electrically conductive pathways, and a fourth layer of a second, flexible, dielectric substrate adheringly contacting said curable adhesive bonding layer; said curable adhesive bonding layer comprising a curable composition comprising a rubber toughener, a bis-benzoxazine represented by Structure I, 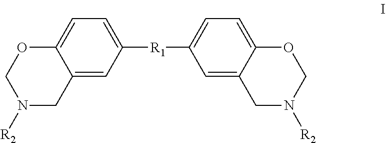
wherein R₁ is a diradical tie molecule and each R₂ can independently be C₁-C₆ alkyl, acyl, aryl; nitrile, or vinyl;
and;
an amino-functionalized triazine composition represented by Structure II 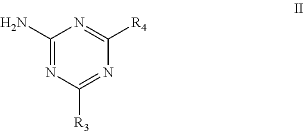
wherein R₃, is H, halogen, hydrocarbyl, hydrocarbyloxy, hydrocarbylthio, amido, sulfonamido, cyclic amino, acyl, morpholino, piperidino, or NR′R″ where R′ and R″ are independently H, alkyl or aromatic, substituted or unsubstituted;
and, R₄ is NH₂ or the radical represented by the Structure III 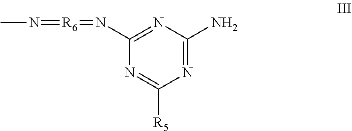
wherein R₅ is H, halogen, hydrocarbyl, hydrocarbyloxy, hydrocarbylthio, amido, sulfonamido, cyclic amino, acyl, morpholino, piperidino, or NR′R″ where R′ and R″ are independently H, alkyl or aromatic, substituted or unsubstituted., and R₆ is an aromatic dianhydride.

2. The multi-layer article of claim 1 wherein the curable composition further comprises a solvent.

3. The multi-layer article of claim 1 wherein the curable composition R₂ is phenyl or substituted phenyl.

4. The multi-layer article of claim 1 wherein the curable composition R₁ is CH₂, C(CH₃)₂, S, dicyclopentadienyl, or phenolphthalein.

5. The multi-layer article of claim 1 wherein the amino-functionalized triazine of the curable composition, R₃ is NH₂.

6. The multi-layer article of claim 1 wherein the amino-functionalized triazine of the curable composition is a di-isoimide represented by Structure IV and isomeric forms thereof 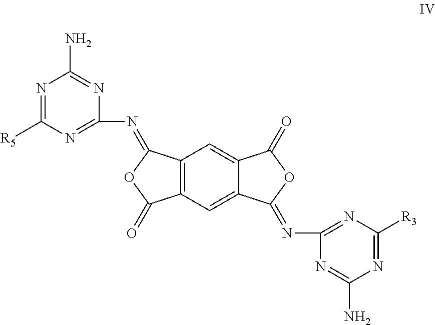
wherein R₃ and R₅ each independently is H, halogen, hydrocarbyl, hydrocarbyloxy, hydrocarbylthio, amido, sulfonamido, cyclic amino, acyl, morpholino, piperidino, or NR′R″ where R′ and R″ are independently H, alkyl or aromatic, substituted or unsubstituted.

7. The multi-layer article of claim 6 wherein R₃ and R₅ are both NH₂.

8. The multi-layer article of claim 7 wherein the bis-benzoxazine of the curable composition, R₂ is phenyl or substituted phenyl, and R₁ is R₁ is CH₂, C(CH₃)₂, S, dicyclopentadienyl, or phenolphthalein.

9. The multi-layer article of claim 8 wherein R₂ is phenyl and R₁ is C(CH₃)₂.

10. The multi-layer article of claim 1 wherein the curable composition further comprises one or more epoxies.

11. The multi-layer article of claim 10 wherein the curable composition further comprises a phenolic or anhydride curing agent wherein the curable composition the one or more epoxies comprises an epoxy of the bisphenol-A type.

12. The multi-layer article of claim 1 wherein the rubber toughener in the curable composition comprises a carboxyl functionalized elastomer.

13. The multi-layer article of claim 11 wherein the curable composition the rubber toughener is a carboxyl functionalized elastomer; R₂ is phenyl or substituted phenyl; R₁ is CH₂, C(CH₃)₂, S, dicyclopentadienyl, or phenolphthalein;
the amino-functionalized triazine is a di-isoimide represented by Structure IV and isomeric forms thereof 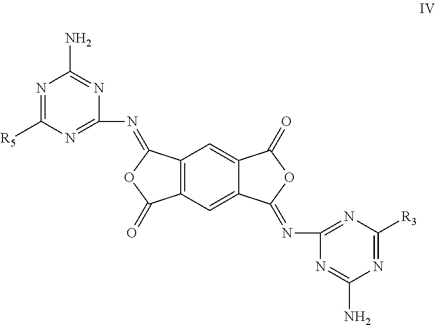
and, wherein R₃ and R₅ are each NH₂.

14. The multi-layer article of claim 1 wherein said first and second dielectric substrates are fully aromatic polyimide film or sheet.

15. A process comprising adhesively contacting the curable adhesive bonding layer of a coated article to at least a portion of discrete conductive pathways disposed upon a dielectric substrate thereby forming a multilayer article; and, applying pressure to the multi-layer article so formed at a temperature in the range of 100 to 250° C. for a period of time in the range of 30 seconds to 5 hours, thereby forming an encapsulated printed wiring board; wherein said multi-layer article comprises in order a first layer of a first dielectric substrate, a second layer of one or more discrete electrically conductive pathways disposed upon said first dielectric substrate, a third layer of a curable adhesive bonding layer adhesively contacting at least a portion of said discrete electrically conducting pathways, and a fourth layer of a second, flexible, dielectric substrate, said curable adhesive bonding layer comprising a curable composition comprising a rubber toughener, a bis-benzoxazine represented by Structure I, 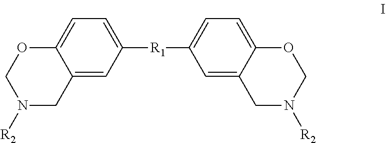
wherein R₁ is a diradical tie molecule—and each R₂ can independently be C₁-C₆ alkyl, acyl, aryl; nitrile, and vinyl;
an amino-functionalized triazine composition represented by Structure II 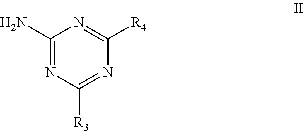
wherein R₃, is H, halogen, hydrocarbyl, hydrocarbyloxy, hydrocarbylthio, amido, sulfonamido, cyclic amino, acyl, morpholino, piperidino, or NR′R″ where R′ and R″ are independently H, alkyl or aromatic, substituted or unsubstituted;
and, R₄ is NH₂ or the radical represented by the Structure III 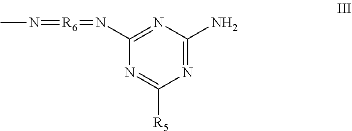
wherein R₅ is H, halogen, hydrocarbyl, hydrocarbyloxy, hydrocarbylthio, amido, sulfonamido, cyclic amino, acyl, morpholino, piperidino, or NR′R″ where R′ and R″ are independently H, alkyl or aromatic, substituted or unsubstituted., and R₆ is an aromatic dianhydride.

16. The process of claim 15 wherein the curable composition further comprises a solvent.

17. The process of claim 18 wherein the amino-functionalized triazine of the curable composition is represented by Structure IV and isomeric forms thereof 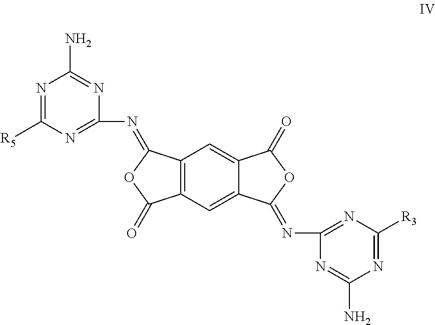
wherein R₃ and R₅ are each NH₂; wherein the bis-benzoxazine of the curable composition, R₂ is phenyl or substituted phenyl; R₁ is CH₂, C(CH₃)₂, S, dicyclopentadienyl, or phenolphthalein;
the curable composition further comprising an epoxy of the bisphenol A type, a rubber toughener, and a phenolic or anhydride curing agent.
